(19) United States
(12) Patent Application Publication
(10) Pub. No.: US 2022/0094002 A1
(43) Pub. Date: Mar. 24, 2022

(54) ELECTROCHEMICAL APPARATUS AND UNMANNED AERIAL VEHICLE

(71) Applicant: Dongguan Poweramp Technology Limited, Dongguan City (CN)

(72) Inventor: Fanggui Peng, Dongguan (CN)

(73) Assignee: Dongguan Poweramp Technology Limited, Dongguan City (CN)

(21) Appl. No.: 17/473,346

(22) Filed: Sep. 13, 2021

(30) Foreign Application Priority Data
Sep. 22, 2020 (CN) 202011000391.9

(51) Int. Cl. H01M 50/204; H01M 10/42; H01M 50/244; H01M 50/262; H01M 50/271; H01M 50/531; H01M 10/613; H01M 10/625; H01M 10/655

(52) U.S. Cl. CPC H01M 50/204; H01M 10/425; H01M 50/244; H01M 50/262; H05K 7/1427; H01M 50/531; H01M 10/613; H01M 10/625; H01M 10/655; H01M 50/271

(57) ABSTRACT

An electrochemical apparatus includes a housing, a circuit board, and a battery module, where the housing includes a cover and a bottom shell, and the cover and the bottom shell form an accommodating cavity; the circuit board is provided in the accommodating cavity, and the circuit board includes a first electrical connection portion; the battery module is accommodated in the accommodating cavity, and the battery module includes a second electrical connection portion; and a first fastening member is provided on an inner side of the bottom shell, and fastens the first electrical connection portion and the second electrical connection portion. With the electrochemical apparatus, short circuits caused by vibrations, extrusions, and frictions of internal structures of the unmanned aerial vehicle using such electrochemical apparatus can be reduced.

### CROSS REFERENCE TO THE RELATED APPLICATIONS

The present application claims priority to Chinese Patent Application No. 202011000391.9, filed on 22 Sep. 2020, the disclosure of which is hereby incorporated by reference in its entirety.

### TECHNICAL FIELD

This application relates to the technical field of batteries, and in particular, to an electrochemical apparatus and an unmanned aerial vehicle.

### BACKGROUND

With the increasingly rapid development of existing mobile apparatuses, people are attaching greater importance to endurance functions of various mobile apparatuses, which require higher-quality batteries for the mobile apparatuses. In existing batteries, a battery module arranged in a housing is connected to a circuit board by a power wire. However, the power wire is usually not fastened. When a battery in use is subjected to external impact, internal structures may vibrate or be squeezed. The increased power wire vibrations will wear out the skin of the power wire, reducing its safety. In addition, frictions between the internal structures caused by vibrations may cause the battery to be short-circuited.

### SUMMARY

In view of this, it is necessary to provide an electrochemical device and an unmanned aerial vehicle, to fasten a connection wire between a battery module and a circuit board in the electrochemical apparatus, so as to reduce short circuits caused by vibrations and frictions.

An electrochemical apparatus for supplying power is provided. The electrochemical apparatus includes a housing, a circuit board, and a battery module, where the housing includes a bottom shell and a cover, and the bottom shell and the cover form an accommodating cavity; the circuit board is provided in the accommodating cavity, and the circuit board includes a first electrical connection portion; the battery module is accommodated in the accommodating cavity, and the battery module includes a second electrical connection portion; and a first fastening member is provided on an inner side of the bottom shell, and fastens the first electrical connection portion and the second electrical connection portion.

In a possible embodiment, the electrochemical apparatus further includes a second fastening member, where the second fastening member is connected to the first fastening member, and used together with the first fastening member to fasten the first electrical connection portion and the second electrical connection portion.

In a possible embodiment, the cover is provided with an opening, and projections of the first fastening member and the second fastening member on the cover are at least partially in the opening.

In a possible embodiment, the first electrical connection portion is a first copper bar provided with a first through hole or a first notch, or is a second through hole or second notch that is provided on the circuit board.

In a possible embodiment, the second electrical connection portion is a second copper bar provided with a third through hole or a third notch.

In a possible embodiment, the first fastening member is a stud, and the stud penetrates the first electrical connection portion and the second electrical connection portion.

In a possible embodiment, the first fastening member is a metal member, and the first fastening member provides electrical conductivity between the first electrical connection portion and the second electrical connection portion.

In a possible embodiment, the first electrical connection portion is connected to the second electrical connection portion.

In a possible embodiment, a glue groove is provided in the cover, the glue groove is filled with glue, and the circuit board is disposed on the glue groove.

In a possible embodiment, the cover further includes a gasket, and the gasket is provided at the opening and configured to seal the opening.

In a possible embodiment, a heat dissipating member is provided on the bottom shell, and the heat dissipating member is configured to dissipate heat from the battery module.

In a possible embodiment, the bottom shell includes a first housing and a second housing, the first housing and the second housing are detachably connected, and the first housing and the second housing together accommodate the battery module.

In a possible embodiment, a threaded rod and a fastening hole that match with each other are provided between the first housing and the second housing, and the threaded rod is provided in the fastening hole to fasten the first housing and the second housing.

In a possible embodiment, the first housing includes a first mounting frame, the second housing includes a second mounting frame, and the heat dissipating members are provided on peripheral sides of the first mounting frame and the second mounting frame, thermally conductive glue is filled between the heat dissipating member and the first mounting frame and between the heat dissipating member and the second mounting frame, and the thermally conductive glue dissipates heat from the battery module.

In a possible embodiment, a guide groove is provided on the first housing, and the guide groove is configured to guide the second electrical connection portion.

In a possible embodiment, the first fastening member is also provided on the first housing, and the first fastening member is located at an edge of the guide groove.

In a possible embodiment, the battery module further includes a plurality of battery cells, the plurality of battery cells are stacked, and a protective member is provided on the battery cell to protect the battery cell.

In a possible embodiment, the battery module further includes an adapting plate, the plurality of battery cells are connected to the adapting plate, and the second electrical connection portion is disposed on the adapting plate.

An unmanned aerial vehicle includes a body and an electrochemical apparatus disposed in the body, where the electrochemical apparatus supplies power to the body, and the electrochemical apparatus is the electrochemical apparatus according to any one of the foregoing embodiments.

In the electrochemical apparatus provided in this application, the first fastening member is provided on an inner side of the bottom shell, and the first electrical connection portion and the second electrical connection portion are connected by using the first fastening portion, thereby fastening the first electrical connection portion and the second electrical connection portion. This can effectively reduce vibrations, extrusions or frictions between the first electrical connection portion and the second electrical connection portion, thereby preventing the electrochemical apparatus from being short-circuited, and improving safety performance.

### BRIEF DESCRIPTION OF DRAWINGS

FIG. 1 is a schematic solid diagram of an electrochemical apparatus according to an embodiment.

FIG. 2 is a schematic exploded view of the electrochemical apparatus shown in FIG. 1.

FIG. 3 is another schematic exploded view of the electrochemical apparatus shown in FIG. 2.

FIG. 4 is a schematic exploded view of a cover and a circuit board.

FIG. 5 is a schematic exploded view of a first housing.

FIG. 6 is a schematic exploded view of a second housing.

FIG. 7 is a schematic exploded view of a battery module.

FIG. 8 is a schematic solid diagram of an unmanned aerial vehicle according to another embodiment.

### REFERENCE SIGNS OF MAIN COMPONENTS

Electrochemical apparatus 100

Housing 1

Cover 10

Cover body 11

Accommodating space 111

Glue groove 112

Fastener 113

Opening 114

First fastening portion 115

First protruding end 116

Handle 12

Gasket 13

First foot pad 14

Buckle 15

Bottom shell 20

First fastening shell 21

First mounting frame 211

Second protruding end 212

Accommodating hole 2121

First guide groove 213

Second guide groove 214

First fastening member 215

Second fastening member 216

Second fastening portion 217, 223

First fastening hole 218

Second fastening shell 22

Second mounting frame 221

Third guide groove 222

Second fastening hole 224

Heat dissipating member 23

Steel sleeve 24

Threaded rod 25

Nut 26

Second foot pad 27

Accommodating cavity A

Circuit board 3

Plate body 31

Sampling wire 311

First electrical connection portion 32

First connecting region portion 321

Second connecting region portion 322

First through hole 323

Charging terminal 33

Battery module 4

Battery cell 41

Tab 411

Foam 42

Radiating plate 43

Protective shell 44

Adapting plate 45

Socket 451

Insulating member 452

Second electrical connection portion 46

Third connection region portion 461

Middle region portion 462

Fourth connection region portion 463

Third through hole 464

Unmanned aerial vehicle 200

Body 5

### DETAILED DESCRIPTION

The following describes the technical solutions in the embodiments of this application with reference to the accompanying drawings in the embodiments of this application. Apparently, the described embodiments are merely some but not all of the embodiments of this application.

It should be noted that when a component is considered to be “connected to” another component, it may be directly connected to the another component or a central component may also exist. When an element is considered to be “disposed” at another element, it may be directly disposed at the another element or an intermediate element may be present. Terms such as “top”, “bottom”, “upper”, “lower”, “left”, “right”, “front”, “rear” and similar expressions used herein are only for description purposes.

Unless otherwise defined, all technical and scientific terms used herein shall have the same meanings as commonly understood by those skilled in the art to which this application belongs. The terms used herein in the specification of this application are only used to describe specific embodiments, and are not intended to limit this application.

This application provides an electrochemical apparatus for supplying power. The electrochemical apparatus includes a housing, a circuit board, and a battery module. The housing includes a bottom shell and a cover, and the bottom shell and the cover form an accommodating cavity. The circuit board is arranged in the accommodating cavity, and includes a first electrical connection portion. The battery module is accommodated in the accommodating cavity, and includes a second electrical connection portion. A first fastening member is provided on an inner side of the bottom shell, and fastens the first electrical connection portion and the second electrical connection portion.

In the electrochemical apparatus provided in this application, the first fastening member is provided on an inner side of the bottom shell, and the first electrical connection portion and the second electrical connection portion are connected by using the first fastening portion, thereby fastening the first electrical connection portion and the second electrical connection portion, implementing electrical conductivity between the battery module and the circuit board for power supply. Compared with the power wire connection, this manner can effectively reduce vibrations, extrusions or frictions of the first electrical connection portion and the second electrical connection portion, thereby reducing short circuits of the electrochemical apparatus due to the worn-out skin of the power wire.

Some embodiments of this application are described in detail below. In absence of conflicts, the following embodiments and features in the embodiments may be combined.

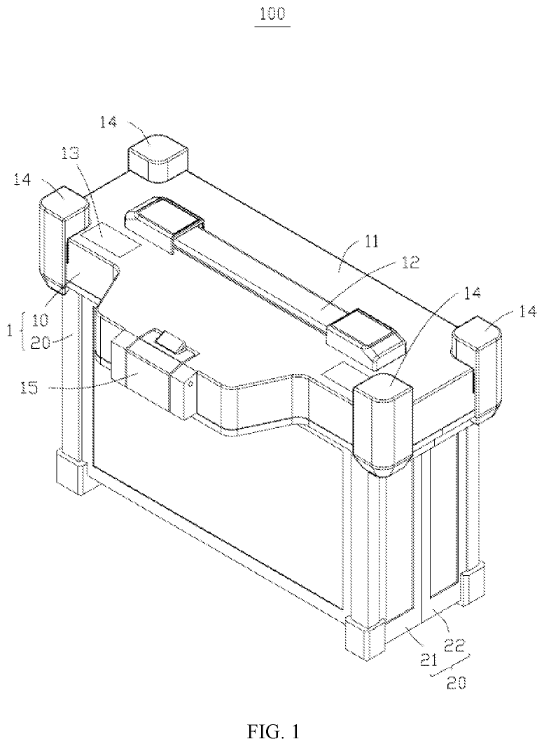

FIG. 1 to FIG. 3 show an electrochemical apparatus 100 for supplying power. The electrochemical apparatus 100 includes a housing 1, a circuit board 3, and a battery module 4. The housing 1 includes a cover 10 and a bottom shell 20, and the cover 10 and the bottom shell 20 form an accommodating cavity A. The circuit board 3 is arranged in the accommodating cavity A, and includes a first electrical connection portion 32. The battery module 4 is accommodated in the accommodating cavity A, and includes a second electrical connection portion 46. A first fastening member 215 is provided on an inner side of the bottom shell 20, and fastens the first electrical connection portion 32 and the second electrical connection portion 46.

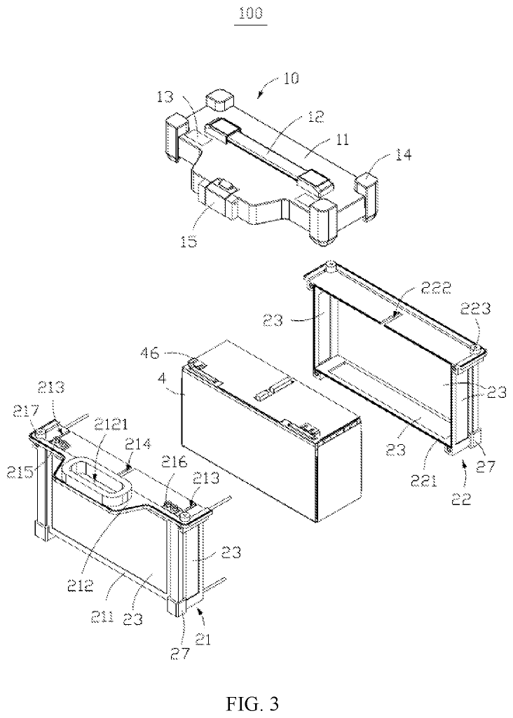

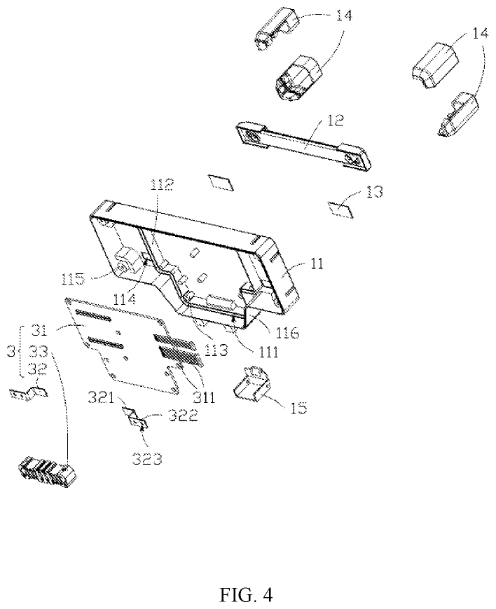

Referring to FIG. 3 and FIG. 4, the cover 10 includes a cover body 11, and a handle 12 is provided on the top of the cover body 11. The cover body 11 is provided on the bottom shell 20. The electrochemical apparatus 100 can be moved or assembled by pulling the handle 12.

The cover body 11 is substantially in a T shape. The lower part of the cover body 11 closer to the bottom shell 20 forms an accommodating space 111. The circuit board 3 is disposed in the accommodating space 111, and the upper end of the bottom shell 20 is accommodated in the accommodating space 111.

A glue groove 112 is also provided in the cover 10. The glue groove 112 is provided in the accommodating space 111, and has a shape similar to that of the accommodating space 111. The glue groove 112 is filled with glue, and the circuit board 3 is disposed on the glue groove 112. Further, the circuit board 3 is fastened to the cover body 11 by a fastener 113, and the fastener 113 may be a screw or a connecting stud. Sealant is filled in the glue groove 112. After the circuit board 3 is fastened into the glue groove 112, the circuit board 3 is bonded by the sealant, so that the circuit board 3 is further secured and components on the circuit board 3 can be protected against water and dust.

The cover body 11 is provided with an opening 114. The opening 114 communicates with the accommodating space 111, and is provided on a side edge of the glue groove 112.

For covering the bottom shell 20, the cover body 11 is further provided with a first fastening portion 115. The first fastening portion 115 is provided at a corner position of the cover body 11, and matches with the bottom shell 20, so as to join the cover 10 and the bottom shell 20.

It can be understood that in other embodiments, the shape of the cover body 11 is not limited thereto. The cover body 11 may be rectangular, circular, or the like, which depends on an apparatus for accommodating the electrochemical apparatus 100.

In an embodiment, to better seal the electrochemical apparatus 100, the cover 10 further includes a gasket 13. The gasket 13 is provided at the opening 114 to seal the opening 114 and prevent water or dust from entering the inside of the cover 10 from the opening 114. The gasket 13 may be disposed at the opening 114 by sealant, or may be fastened at the opening 114 by a fastener 113. The gasket 13 may be a rubber gasket or a gasket of the same material as the cover body 11.

In this embodiment, two such openings 114 are provided, and correspondingly, two such gaskets 13 are provided. It can be understood that in other embodiments, the number of the openings 114 and the number of the gaskets 13 are not limited thereto.

In an embodiment, to better protect the cover body 11, the cover further includes a first foot pad 14, and the first foot pad 14 sleeves the corner of the cover body 11, so that when the cover body 11 collides with an external structure, the first foot pad 14 can protect the cover body 11 from damage. In addition, when the cover body 11 joins the bottom shell 20, the first foot pad 14 can be snapped onto the bottom shell 20 to protect the bottom shell 20. In this embodiment, the cover 10 includes four such first foot pads 14, and the four first foot pads 14 are respectively disposed at four corners.

It can be understood that in other embodiments, the number of the first foot pads 14 is not limited thereto.

In an embodiment, for connection with an external mechanism, the cover 10 further includes a buckle 15. The buckle 15 is provided at an end position of a first protruding end 116 of the cover body 11, that is, at a lower end position of the “T” shape. With the buckle 15, the electrochemical apparatus 100 is fastened to the external mechanism.

Referring to FIG. 3, the bottom shell 20 includes a first fastening shell 21 and a second fastening shell 22, the first fastening shell 21 and the second fastening shell 22 are detachably connected, and the first fastening shell 21 and the second fastening shell 22 together accommodate the battery module 4. The first fastening shell 21 and the second fastening shell 22 are provided with a heat dissipating member 23 to dissipate heat from the battery module 4 in the bottom shell 20. The cover 10 is provided on the upper ends of the first fastening shell 21 and the second fastening shell 22 and is fastened to the first fastening shell 21 and the second fastening shell 22. Further, positions at which the cover 10 is in contact with the first fastening shell 21 and the second fastening shell 22 are filled with sealant, which can further secure the cover 10 to the first fastening shell 21 and the second fastening shell 22, and can also provide protection against water and dust.

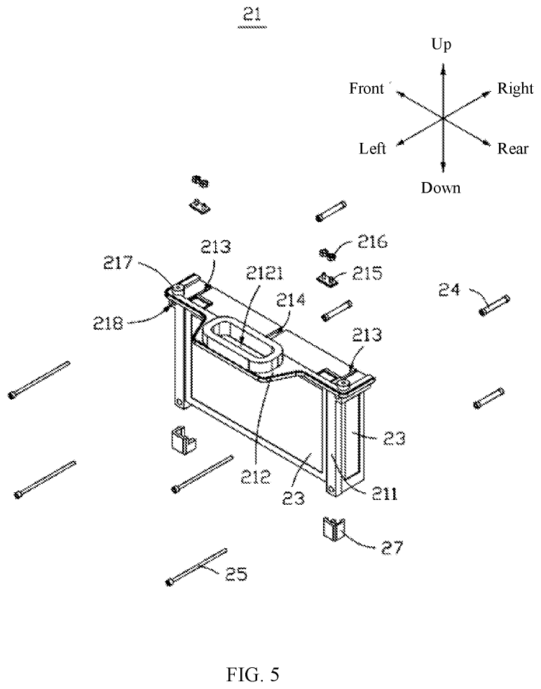

Referring to FIG. 3 and FIG. 5, specifically, the first fastening shell 21 includes a first mounting frame 211, the first mounting frame 211 is a hollowed structure, and the heat dissipating members 23 are provided on the peripheral sides of the first mounting frame 211 to fill the first mounting frame 211, so as to accommodate part of the battery module 4. Further, the first mounting frame 211 is provided with four heat dissipating members 23, and the four heat dissipating members 23 are respectively disposed on the front side, rear side, left side, and bottom of the first mounting frame 211.

he first mounting frame 211 matches the contour of the cover 10, and is provided with a second protruding end 212 that matches with the first protruding end 116 of the cover body 11. An accommodating hole 2121 is provided on the second protruding end 212.

In an embodiment, a first guide groove 213 is provided on an upper end plate of the first mounting frame 211 closer to the cover 10. The first guide groove 213 is provided at the front and rear end positions of the first mounting frame 211, to guide the movement of the second electrical connection portion 46, and allow the second electrical connection portion 46 to extend out of the bottom shell 20.

In an embodiment, a second guide groove 214 is further provided at a middle position of the upper end plate of the first mounting frame 211.

The first fastening member 215 is provided on the first mounting frame 211 at a position closer to the first guide groove 213. During assembly of the battery module 4, the first fastening member 215 can be used to fasten the first electrical connection portion 32 and the second electrical connection portion 46, to avoid dragging or damaging the structures on the circuit board 3 and the internal structures of the battery module 4.

In an embodiment, the first fastening member 215 is a metal member, and when the first fastening member 215 is fixedly connected to the first electrical connection portion 32 and the second electrical connection portion 46, the first electrical connection portion 32 and the second electrical connection portion 46 can be electrically conducted.

In another embodiment, the first fastening member 215 may be a plastic member.

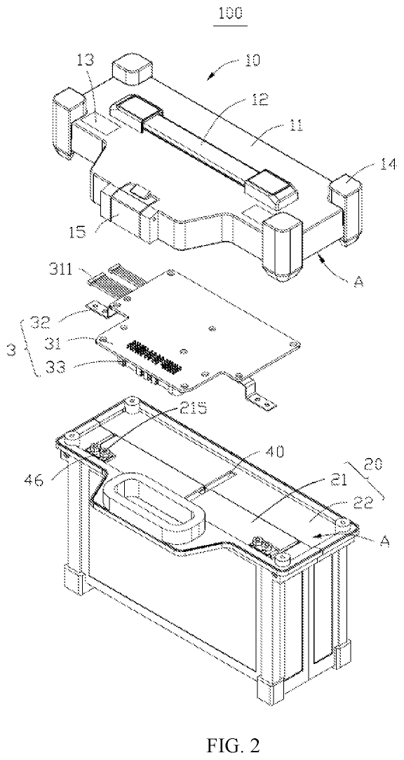

Referring to FIG. 2 and FIG. 5, in a specific embodiment, the first fastening member 215 is a fastening stud, and the stud penetrates the first electrical connection portion 32 and the second electrical connection portion 46. In this embodiment, the first fastening member 215 is embedded in the first mounting frame 211. It can be understood that in other embodiments, the first fastening member 215 may be integrally formed with the first mounting frame 211.

Referring to FIG. 5, the electrochemical apparatus further includes a second fastening member 216, and the second fastening member 216 is connected to the first fastening member 215. If the first fastening member 215 is made of plastic, the first electrical connection portion 32 and the second electrical connection portion 46 are located between the first fastening member 215 and the second fastening member 216 and are fastened by using the first fastening member 215 and the second fastening member 216 jointly. In addition, the first electrical connection portion 32 is connected to the second electrical connection portion 46.

In an embodiment, the first fastening member 215 is a stud, and to match with the first fastening member 215, the second fastening member 216 is a nut. It can be understood that, in other embodiments, the first fastening member 215 and the second fastening member 216 may be replaced with other structures that can fasten the first electrical connection portion 32 and the second electrical connection portion 46, for example, a magnet structure that can attract each other.

Referring to FIG. 2 and FIG. 5, further, projections of the first fastening member 215 and the second fastening member 216 on the cover 10 are at least partially in the opening 114. If the gasket 13 is removed from the opening 114, the second fastening member 216 in the accommodating cavity A can be adjusted from the opening 114, so as to fasten the first electrical connection portion 32 and the second electrical connection portion 46.

In an embodiment, for being fastened to the cover 10, the first mounting frame 211 is further provided with a second fastening portion 217 that matches with the first fastening portion 115, so that the first mounting frame 211 can better adapt to and be fastened to the cover 10. Further, if the first fastening portion 115 and the second fastening portion 217 are fastening posts with a screw hole, the first fastening portion 115 and the second fastening portion 217 are connected by a long stud and a nut, so as to fasten the cover 10 and the first mounting frame 211.

It can be understood that, in other embodiments, the first fastening portion 115 and the second fastening portion 217 are not limited thereto. For example, the first fastening portion 115 is a stepped hole and the second fastening portion 217 is a fastening post, and the cover 10 and the first mounting frame 211 can still be fastened by using a stud and a nut.

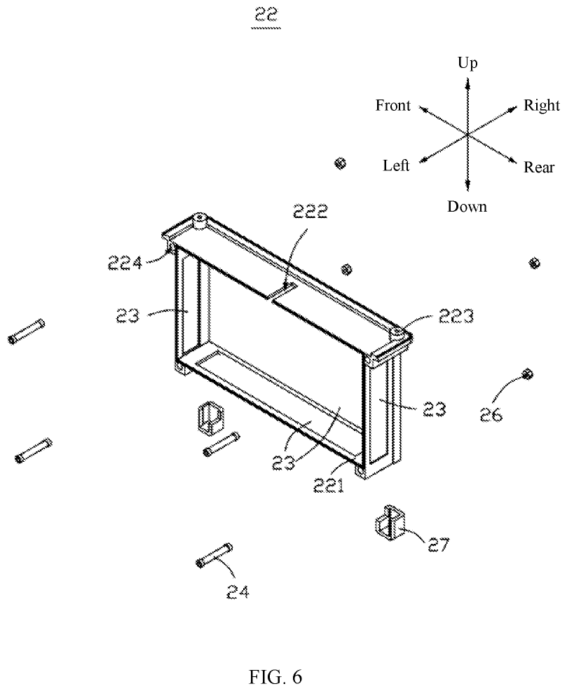

Referring to FIG. 2 and FIG. 6, the second fastening shell 22 includes a second mounting frame 221, the second mounting frame 221 is a hollowed structure, and the heat dissipating members 23 are provided on the peripheral sides of the second mounting frame 221 to fill the second mounting frame 221, so as to accommodate part of the battery module 4. Like the first mounting frame 211, the second mounting frame 221 is also provided with four such heat dissipating members 23, and the four heat dissipating members 23 are respectively disposed on the front side, rear side, right side, and bottom of the second mounting frame 221.

An upper end jointly formed by the second mounting frame 221 and the first mounting frame 211 matches the contour of the cover 10 so that the cover 10 can be fastened to the bottom shell 20.

In an embodiment, a third guide groove 222 is provided at a middle position of an upper end plate of the second mounting frame 221, the third guide groove 222 communicates with the second guide groove 214, and part of the battery module 4 protrudes from the second guide groove 214 and the third guide groove 222.

In an embodiment, the second mounting frame 221 is also provided with a second fastening portion 223 that matches with the first fastening portion 115, so that the second mounting frame 221 can better adapt to and be fastened to the cover 10. The manner for fastening the second fastening portion 223 and the first fastening portion 115 is the same as that for fastening the second fastening portion 217 of the first mounting frame 211 and the first fastening portion 115. Details are not described herein again.

Referring to FIG. 5 and FIG. 6, the heat dissipating members 23 are embedded in the first mounting frame 211 and the second mounting frame 221, and are formed through an integral injection molding process. The heat dissipating members 23 are provided so that heat can be dissipated from the battery module 4 inside the bottom shell 20. Further, gaps between the heat dissipating members 23 and the first mounting frame 211 and the second mounting frame 221 are filled with thermally conductive glue. The heat dissipating members 23 and the thermally conductive glue simultaneously dissipate heat from the battery module 4, thereby improving heat dissipation efficiency. In addition, by filling the thermally conductive glue, overall structural strength of the first mounting frame 211 and the second mounting frame 221 is increased.

In this embodiment, the heat dissipating member 23 is a heat dissipation aluminum plate. It can be understood that in other embodiments, the heat dissipating member 23 may be aluminum alloy, magnesium aluminum alloy, or the like.

Referring to FIG. 5 and FIG. 6, in an embodiment, to allow the first fastening shell 21 to be detachably connected to the second fastening shell 22, the bottom shell 20 further includes a steel sleeve 24, a threaded rod 25, and a nut 26. Specifically, to facilitate installation of the steel sleeve 24 and the threaded rod 25, a first fastening hole 218 is provided on the left of the first mounting frame 211, the steel sleeve 24 is disposed in the first fastening hole 218, and one end of the threaded rod 25 is fastened in the steel sleeve 24 and extends toward the second fastening shell 22. A second fastening hole 224 is provided on the right of the second mounting frame 221, the steel sleeve 24 is disposed in the second fastening hole 224, and the other end of the threaded rod 25 extends into the second fastening hole 224, and fastened by using the nut 26, thereby connecting the first mounting frame 211 and the second mounting frame 221. The contact positions between the first mounting frame 211 and the second mounting frame 221 are filled with sealant to further secure the first mounting frame 211 and the second mounting frame 221 and prevent water and dust from entering inside.

In this embodiment, four such threaded rods 25 are provided on the first mounting frame 211 for connection with the second mounting frame 221. The threaded rod 25 has a guiding function, and can also enhance the strength of the entire bottom shell 20. It can be understood that, in other embodiments, the first fastening shell 21 and the second fastening shell 22 can be connected in other ways. For example, in a snap-on manner, a hook is provided on the first mounting frame 211, and a fastening post is provided on the second mounting frame 221, through which the first fastening shell 21 and the second fastening shell 22 can also be fastened.

In an embodiment, to protect the first fastening shell 21 and the second fastening shell 22, the bottom shell 20 further includes a second foot pad 27. The second foot pad 27 is provided at the lower corners of the first fastening shell 21 and the second fastening shell 22 to prevent the first fastening shell 21 and the second fastening shell 22 from being damaged when subjected to collision.

Still referring to FIG. 4, the circuit board 3 includes the first electrical connection portion 32, and further includes a plate body 31, and the first electrical connection portion 32 is connected on the plate body 31.

The contour of the plate body 31 is the same as that of the glue groove 112. The plate body 31 is disposed on the glue groove 112, and fastened to the cover body 11 by using the fastener 113 together with sealant, so as to protect the components arranged on the plate body 31. The plate body 31 is also provided with a sampling wire 311 to sample the accuracy on the plate body 31, such as resistance and current.

In this embodiment, the plate body 31 is a Battery Management System (BMS) board. It can be understood that, in other embodiments, the plate body 31 can be replaced with another plate body with equivalent functions or effects, such as a PCM board.

In this embodiment, the first electrical connection portion 32 is substantially ladder-like, and can be formed by bending a linear first electrical connection portion 32. In an embodiment, the first electrical connection portion 32 is a first copper bar. It can be understood that, in other embodiments, the first electrical connection portion 32 can be replaced with another structure with equivalent functions or effects.

The first electrical connection portion 32 includes a first connection region portion 321 and a second connection region portion 322, and the first connection region portion 321 is electrically connected to the plate body 31 by using the surface-mount technology. The second connection region portion 322 of the first electrical connection portion 32 is connected to the first fastening member 215, and the second connection region portion 322 is provided with a first through hole 323. The first fastening member 215 is placed into the first through hole 323 to fasten the first electrical connection portion 32.

It can be understood that, in another embodiment, the first through hole 323 can be replaced with a first notch, and the first fastening member 215 is placed into the first notch, which can also fasten the first electrical connection portion 32.

In other embodiments, the first electrical connection portion 32 may be a second through hole or second notch that is provided on the circuit board 3. Specifically, the first electrical connection portion 32 is the second through hole or second notch that is provided on the plate body 31. A conductive contact is provided on the inner side wall of the second through hole or the second notch. When the first fastening member 215 is a metal member, the conductive contact is electrically conductive with the second electrical connection portion 46 through the first fastening member 215. Alternatively, a conductive contact is provided at a position that is on a surface of the plate body 31 closer to the battery module 4 and that corresponds to the second electrical connection portion 46, and when the first fastening member 215 is a plastic member, the conductive contact is directly electrically conductive with the second electrical connection portion 46.

The circuit board 3 further includes a charging terminal 33. The charging terminal 33 is located in the accommodating hole 2121 and electrically connected to the plate body 31, so as to be electrically connected to an external mechanism and output power of the electrochemical apparatus 100.

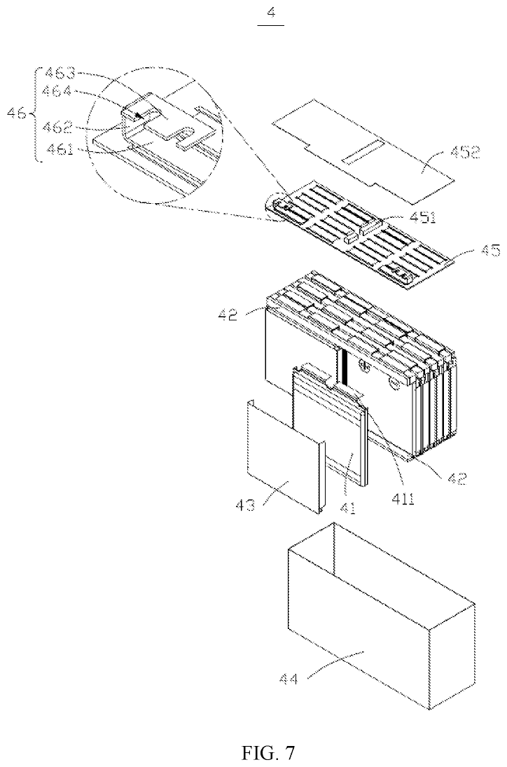

Referring to FIG. 7, the battery module 4 includes a plurality of battery cells 41, and the plurality of battery cells 41 are stacked, and two adjacent battery cells 41 can be fastened by using glue. Specifically, the plurality of battery cells 41 are arranged in two columns. The battery cell 41 is provided with a tab 411. The method for connecting the tab 411 and the battery cell 41 belongs to the prior art, and is not described herein.

In an embodiment, to protect the battery cell 41, the battery module 4 further includes protective members, and the protective members are provided at the upper and lower ends of the battery cell 41. The tab 411 is also provided with such protective member. Further, in this embodiment, the protective member is a foam 42. The foam 42 can alleviate external impact on the battery cell 41 and therefore protect the battery cell 41.

It can be understood that, in other embodiments, the protective member can be replaced with another structure with equivalent functions or effects. For example, the protective member can be replaced with elastic rubber.

In an embodiment, to better dissipate heat from the battery cell 41, the battery module 4 further includes a heat dissipation plate 43. The heat dissipation plate 43 is disposed on a surface of the battery cell 41. Further, the heat dissipation plate 43 is a heat dissipation aluminum plate. It can be understood that the heat dissipation plate 43 is not limited thereto.

In an embodiment, the battery module 4 further includes a protective shell 44. The protective shell 44 is substantially a hollowed shell without an upper cover. A plurality of the battery cells 41 are accommodated in the protective shell 44. The volume of the protective shell 44 is approximately the same as the volume of the plurality of the battery cells 41 to prevent the battery cells 41 from moving in the protective shell 44. Further, the protective shell 44 is made of an epoxy resin board. The epoxy resin board makes the protective shell 44 insulative and not prone to deformation.

The battery module 4 further includes an adapting plate 45. The adapting plate 45 is arranged on the upper end of the battery cell 41 and connected to the tab 411 through a nickel sheet (not shown in the figure). A socket 451 is provided at a substantially middle position of the adapting plate 45. The socket 451 is welded to the adapting plate 45. The socket 451 protrudes from the bottom shell 20 through the second guide groove 214 and the third guide groove 222. Sampling output of the adapting plate 45 is implemented through the socket 451. The provision of the socket 451 facilitates the maintenance of the adapting plate 45. If the socket 451 is faulty, it is unnecessary to replace the entire adapting plate 45, reducing maintenance costs.

The adapting plate 45 is also provided with an insulating member 452. The contour of the insulating member 452 matches that of the adapting plate 45, which can prevent electric leakage of the adapting plate 45. Further, the insulating member 452 is insulating paper. It can be understood that in other embodiments, the insulating member 452 can be replaced with an insulation washer.

The second electrical connection portion 46 is welded to the adapting plate 45, and further, the second electrical connection portion 46 is a second copper bar. It can be understood that, in other embodiments, the second electrical connection portion 46 can be replaced with another structure with equivalent functions or effects.

The second electrical connection portion 46 includes a third connection region portion 461, a middle region portion 462, and a fourth connection region portion 463. The third connection region portion 461, the middle region portion 462, and the fourth connection region portion 463 roughly form a U-shaped structure.

The third connection region portion 461 is welded to the adapting plate 45, and the middle region portion 462 is soft and can be bent. When the third connection region portion 461 is being weld to the adapting plate 45, the middle region portion 462 can be bent to bypass the laser. In addition, when the second electrical connection portion 46 is connected to the first electrical connection portion 32, the bending of the middle region portion 462 can reduce the pressure caused by manufacturing and installation errors. A third through hole 464 is provided in the fourth connection region portion 463, and the first fastening member 215 can be clamped in the third through hole 464. In an embodiment, the third through hole 464 is an unclosed through hole, allowing the battery module 4 and the housing 1 to be assembled more conveniently.

In another embodiment, the third through hole 464 can be replaced with a third notch, and the first fastening member 215 can also be clamped in the third notch.

Referring to FIG. 3 and FIG. 4, when the first electrical connection portion 32 and the second electrical connection portion 46 are being fastened, the first fastening member 215 penetrates the third through hole 464 and the first through hole 323, and then fastens the first electrical connection portion 32 and the second electrical connection portion 46 with the second fastening member 216.

In this embodiment, the battery module 4 includes two second electrical connection portions 46, and the two second electrical connection portions 46 respectively serve as a main positive electrode and a main negative electrode of the battery cells 41. A copper busbar connection can achieve better fastening than the power wire connection, and also reduces the difficulty of laser welding without dragging the tab 411.

Still referring to FIG. 3, in the process of assembling the electrochemical apparatus 100, the first fastening shell 21 and the second fastening shell 22 are arranged on the outside of the battery module 4. The first fastening shell 21 and the second fastening shell 22 are fastened in a plug-in manner. The second electrical connection portion 46 moves along the first guide groove 213, so that the middle region portion 462 is located in the first guide groove 213, and the fourth connection region portion 463 is located outside the bottom shell 20 and clamped on the first fastening member 215.

The cover 10 is plug-connected to the bottom shell 20, the second connection region portion 322 of the first electrical connection portion 32 is fastened to the first fastening member 215, and the second fastening member 216 can be locked through the opening 114, thereby fastening the first electrical connection portion 32 and the second electrical connection portion 46. Finally, the gasket 13 is disposed at the opening 114 to seal it.

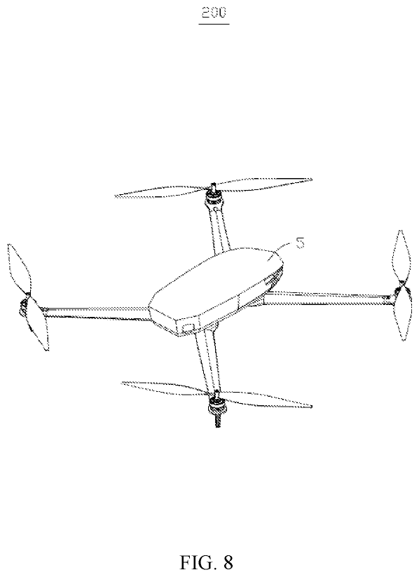

Referring to FIG. 8, in another embodiment, this application further provides an unmanned aerial vehicle 200. The unmanned aerial vehicle 200 includes a body 5 and an electrochemical apparatus 100 provided in the body 5. The electrochemical apparatus 100 supplies power to the body 5, and the electrochemical apparatus 100 can be fastened to the body 5 by the buckle 15. The electrochemical apparatus 100 is the electrochemical apparatus 100 described in any one of the foregoing embodiments, and details are not described herein again.

In summary, the embodiments of this application provide the electrochemical apparatus 100 and the unmanned aerial vehicle 200 using the electrochemical apparatus. In the electrochemical apparatus 100, the first fastening member 215 is provided on the inner side of the bottom shell 20 to connect the first electrical connection portion 32 and the second electrical connection portion 46, thereby preventing the first electrical connection portion 32 and the second electrical connection portion 46 from moving. Further, the second fastening member 216 is placed into the accommodating cavity A through the opening 114 to further secure the first electrical connection portion 32 and the second electrical connection portion 46. This can reduce the vibrations, extrusions, or frictions of the first electrical connection portion 32 and the second electrical connection portion 46, thereby preventing the first electrical connection portion 32 and the second electrical connection portion 46 from being worn out, and further preventing the electrochemical apparatus 100 from being short-circuited.

The first electrical connection portion 32 and the second electrical connection portion 46 are fastened by using the studs and nuts, which reduces the assembly cost and difficulty. If the first electrical connection portion 32 and the second electrical connection portion 46 can be fastened by using the first fastening member 215 alone, the second fastening member may not be used. In addition, the glue groove 112 is provided and sealant is filled between the cover 10 and the bottom shell 20, so that the electrochemical apparatus 100 is effectively protected against water and dust, with a waterproof and dustproof rating as high as IP67. The heat dissipating member 23 is built in the first mounting frame 211 and the second mounting frame 221, with the thermally conductive glue filled, thereby improving the heat dissipation efficiency of the electrochemical apparatus 100.

In addition, those of ordinary skill in the art should realize that the foregoing embodiments are only used to illustrate this application, but not to limit this application, and any appropriate changes and variations made to the foregoing embodiments within the essential spirit of this application shall fall within the scope of the claims disclosed by this application.

What is claimed is:

1. An electrochemical apparatus for supplying power, wherein the electrochemical apparatus comprises:
a housing, wherein the housing comprises a bottom shell and a cover, and the bottom shell and the cover form an accommodating cavity;
a circuit board provided in the accommodating cavity, wherein the circuit board comprises a first electrical connection portion; and
a battery module accommodated in the accommodating cavity, wherein the battery module comprises a second electrical connection portion;
wherein a first fastening member is provided on an inner side of the bottom shell, and fastens the first electrical connection portion and the second electrical connection portion.

2. The electrochemical apparatus according to claim 1, further comprising a second fastening member, wherein the second fastening member is connected to the first fastening member, and used together with the first fastening member to fasten the first electrical connection portion and the second electrical connection portion.

3. The electrochemical apparatus according to claim 2, wherein the cover is provided with an opening, and projections of the first fastening member and the second fastening member on the cover are at least partially in the opening.

4. The electrochemical apparatus according to claim 1, wherein the first electrical connection portion is a first copper bar provided with a first through hole or a first notch, or is a second through hole or a second notch provided in the circuit board.

5. The electrochemical apparatus according to claim 1, wherein the second electrical connection portion is a second copper bar provided with a third through hole or a third notch.

6. The electrochemical apparatus according to claim 1, wherein the first fastening member is a stud, and the stud penetrates the first electrical connection portion and the second electrical connection portion.

7. The electrochemical apparatus according to claim 1, wherein the first fastening member is a metal member, and the first fastening member provides electrical conductivity between the first electrical connection portion and the second electrical connection portion.

8. The electrochemical apparatus according to claim 1, wherein the first electrical connection portion is connected to the second electrical connection portion.

9. The electrochemical apparatus according to claim 1, wherein a glue groove is provided in the cover, the glue groove is filled with a glue, and the circuit board is disposed in the glue groove.

10. The electrochemical apparatus according to claim 3, wherein the cover further comprises a gasket, and the gasket is provided at the opening and configured to seal the opening.

11. The electrochemical apparatus according to claim 1, wherein the bottom shell comprises a first housing and a second housing, the first housing and the second housing are detachably connected, and the first housing and the second housing together accommodate the battery module.

12. The electrochemical apparatus according to claim 11, wherein a threaded rod and a fastening hole that match with each other are provided between the first housing and the second housing, and the threaded rod is provided in the fastening hole to fasten the first housing and the second housing.

13. The electrochemical apparatus according to claim 11, wherein a heat dissipating member is provided on the bottom shell, and the heat dissipating member is configured to dissipate heat from the battery module.

14. The electrochemical apparatus according to claim 12, wherein the first housing comprises a first mounting frame, the second housing comprises a second mounting frame, and the heat dissipating members are provided on peripheral sides of the first mounting frame and the second mounting frame, a thermally conductive glue is filled between the heat dissipating member and the first mounting frame and between the heat dissipating member and the second mounting frame, and the thermally conductive glue dissipates heat from the battery module.

15. The electrochemical apparatus according to claim 11, wherein a guide groove is provided on the first housing, and the guide groove is configured to guide the second electrical connection portion.

16. The electrochemical apparatus according to claim 15, wherein the second electrical connection portion comprises a third connection region portion, a middle region portion, and a fourth connection region portion, the third connection is connected to the battery module, the middle region portion is located in the first guide groove the fourth connection region portion is located outside the bottom shell and clamped on the first fastening member.

17. The electrochemical apparatus according to claim 15, wherein the first fastening member is provided on the first housing, and the first fastening member is located at an edge of the guide groove.

18. The electrochemical apparatus according to claim 1, wherein the battery module further comprises a plurality of battery cells, the plurality of battery cells are stacked, and a protective member is provided on the battery cell to protect the battery cell.

19. The electrochemical apparatus according to claim 18, wherein the battery module further comprises an adapting plate, the plurality of battery cells are connected to the adapting plate, and the second electrical connection portion is disposed on the adapting plate.

20. An unmanned aerial vehicle, wherein the unmanned aerial vehicle comprises a body and an electrochemical apparatus disposed in the body, the electrochemical apparatus supplies power to the body, and the electrochemical apparatus is the electrochemical apparatus according to claim 1.
